(19) United States
(12) Patent Application Publication
(10) Pub. No.: US 2026/0230056 A1
(43) Pub. Date: Aug. 6, 2026

(54) APPARATUS FOR GENERATION AND TRANSMISSION OF MECHANICAL VIBRATIONS TO MEDIA

(71) Applicant: Dr. Hielscher GmbH, Teltow (DE)

(72) Inventors: Thomas HIELSCHER, Potsdam (DE); Holger HIELSCHER, Rangsdorf (DE); Harald HIELSCHER, Stahnsdorf (DE)

(21) Appl. No.: 19/530,910

(22) Filed: Feb. 5, 2026

(30) Foreign Application Priority Data
Feb. 6, 2025 (DE) 102025104382.5

(51) Int. Cl. H03H 9/17; B06B 1/06; B06B 3/00

(52) U.S. Cl. CPC H03H 9/17; B06B 1/06; B06B 3/00

(57) ABSTRACT

Provided is an apparatus for generation and transmission of mechanical vibrations to media. The apparatus for generation and transmission of mechanical vibrations to media comprises at least one resonator comprising or consisting of at least one lambda/2 resonance oscillator, which for each lambda/2 is assembled from or comprises at least two substantially lambda/4 segments, at least one piezoelectric element, and at least one external body in a positive-fit and/or material-bonding and/or friction-locked manner, wherein a resonance length of the substantially lambda/4 segments is less than or equal to lambda/4, the assembly of which results in a resonance length of at least one lambda/2.

### CROSS-REFERENCE TO RELATED APPLICATION

This application claims priority to German Patent Application No. 102025104382.5, filed on February 6, 2025, the entire disclosure of which is incorporated herein by reference.

### TECHNICAL FIELD

The invention relates to an apparatus for generation and transmission of mechanical vibrations to media.

### BACKGROUND

A resonator can be excited to a resonant vibration at any arbitrary surface point, a plurality of arbitrary surface points, or one or more partial surfaces. A resonator can have a plurality of resonance frequencies. The resonance frequency of a resonator can be influenced, among other things, by the material, by the geometry, and by the temperature of the resonator and by its contact with a medium or with a container.

The mechanical power transmitted from a resonator via an active surface to a medium or to a container depends, among other things, on the properties of the medium, such as temperature, viscosity, or pressure, on the size of the active surface, and on the normal amplitude of the active surface points or on the container properties.

Resonators are known which, for the generation of the resonant vibration, consist of longitudinally oscillating segments and piezoelectric elements, which are connected to one another in a friction-locked manner.

### SUMMARY

The invention is defined by the appended claims. The invention relates to an apparatus for generation and transmission of mechanical vibrations to media or to a container filled with at least one medium. The media can be solid and/or liquid and/or gaseous.

The apparatus according to claim 1 comprises at least one resonator comprising or consisting of at least one lambda/2 resonance oscillator, which for each lambda/2 is assembled from or comprises at least two substantially lambda/4 segments, at least one piezoelectric element, and at least one external body, preferably external bodies, in a positive-fit and/or material-bonding and/or friction-locked manner, wherein a resonance length of the (substantially) lambda/4 segments is less than or equal to lambda/4 and their assembly results in a resonance length of at least one lambda/2. Lambda corresponds to the resonance wavelength of the wave to be emitted by the resonator, in particular an ultrasonic wave. In other words, lambda/2 is half the wavelength of a standing wave occurring during resonance phenomena. By means of the at least one lambda/2 resonance oscillator set into resonant vibrations via the piezoelectric element, mechanical vibrations can thus be transmitted to surrounding media. The two lambda/4 segments are referred to as substantially lambda/4 segments because, in order to achieve an assembled resonance length of lambda/2 by means of two lambda/4 segments, a respective resonance length of slightly less than lambda/4 is required, since at least the piezoelectric element and the at least one external body can likewise contribute a portion to the resonance length of the resonator.

Material-bonding means that components are directly connected to one another by physical or material-technical properties, for example by interference fit or clamping. This involves a physical connection without additives, i.e., in the case of material-bonding connections, the material itself is used for the connection. This has the advantage that no further elements are required for connecting the components, whereby the total length of the resonator can be reduced or kept small.

Friction-locked means that components are held together by external forces (e.g., pressure, tension) without the components having a fixed positive-fit connection (e.g., screws, clamps). Friction-locked connections are based on forces that hold the components together (e.g., by a screw that exerts pressure on the component). Friction-locked connections do not represent a permanent positive fit. In other words, friction-locked connections have the advantage that the connections can be released or restored again (reversibly). This facilitates the production of the resonator and the replacement of components, for example defective components and/or components with other functions.

Positive-fit means that components are connected to one another by geometric fit, such that they are mechanically fixedly connected to one another without additional assistance, such as bonding or welding, being required. Positive-fit connections are based on the shape of the components, which interlock in such a way that a fixed connection is created (e.g., protrusions that engage in corresponding grooves). This has the advantage that no further elements are required for connecting the components, whereby the total length of the resonator can be reduced or kept as small as possible.

The at least one external body preferably comprises a holding body, which serves to fasten the resonator to an external component, and/or one or a plurality of layers for electrical insulation, for example insulating disks made of a suitable insulation material. The holding body is preferably arranged between a lambda/4 segment and the piezoelectric element, in particular arranged directly therebetween. The layer for electrical insulation is preferably arranged at or in direct contact with the piezoelectric element. This has the advantage that the piezoelectric element is electrically insulated from the lambda/4 segments, whereby the handleability of the resonator is increased. Preferably, one layer for electrical insulation each, for example one insulating disk each, is arranged at the opposite contact surfaces of the piezoelectric element (along the direction of vibration) in order to achieve an insulation of the piezoelectric element on both sides. The piezoelectric element is preferably arranged in a vibration node of the standing wave of the resonator. Preferably, a plurality of piezoelectric elements are provided.

The invention enables a generation and transmission of vibrations with at least one active surface on the resonator surface standing in contact with the medium.

In a preferred embodiment, at least one of the lambda/4 segments contains a stepped end larger in its dimension, which leads to a reduction of the resonance length of the resonator. In other words, the at least one lambda/4 segment comprises an end or a section which is increased in its diameter or protrudes relative to a diameter of the remaining resonator, for example the diameter of the piezoelectric element. Preferably, the diameter of the end or of the section of the at least one lambda/4 segment is increased by at least 10 percent, at least 20 percent, at least 30 percent, at least 40 percent, at least 50 percent, at least 60 percent, at least 70 percent, at least 80 percent, at least 90 percent, or at least 100 percent of the diameter of the remaining resonator, for example of the diameter of the piezoelectric element. By increasing the diameter of the end of the lambda/4 segment, an overall higher mass of the lambda/4 segment is achieved, whereby the vibration properties of the lambda/4 segment are changed. In particular, the resonance length of the lambda/4 segment is shortened in this case. In order to maintain a constant (desired) resonance frequency, the length of the lambda/4 segment is preferably shortened to such an extent that the change in the vibration behavior caused by the increase in diameter is canceled out by the lower resonance length of the lambda/4 segment. Due to the shortened resonance length of the lambda/4 segment, the required installation space along the direction of vibration is advantageously reduced. A smaller structural size expands the application possibilities of the apparatus for generation and transmission of mechanical vibrations to media.

In a further preferred embodiment, at least one of the lambda/4 segments contains a stepped end larger in its dimension, wherein the stepped end functions predominantly as a flexural oscillator. A flexural oscillator describes a vibration in which a component or body moves by bending. This means that the component undergoes a bending along its length, in which different parts of the body move by different distances and with different phases. A flexural vibration preferably occurs when the diameter of the stepped end of the lambda/4 segment is increased by at least 1.2 times the diameter of the remaining resonator, for example the diameter of the piezoelectric element. In other words, the portion of the transmitted vibration based on a flexural vibration of the lambda/4 segment becomes larger, the larger the diameter of the stepped end of the lambda/4 segment is formed in comparison to the diameter of the remaining resonator, for example the diameter of the piezoelectric element. For example, from an increase in the diameter of the lambda/4 segment by at least 1.4 times the diameter of the remaining resonator, for example the diameter of the piezoelectric element, the stepped end or the lambda/4 segment functions predominantly as a flexural oscillator. Flexural oscillators have the advantage that they can have several vibration modes (e.g., first, second, third bending modes), which can be used in many engineering and acoustic applications. These different modes offer versatile control possibilities and fine adjustment of vibrations and sound.

In a further preferred embodiment, at least one of the lambda/4 segments contains a stepped end larger in its dimension, wherein the stepped end functions predominantly as a longitudinal oscillator. A longitudinal oscillator describes a vibration in which the body moves in a longitudinal direction, i.e., oscillates back and forth along its own axis. Longitudinal vibrations are substantially generated in the regions of the lambda/4 segment which correspond to the diameter of the resonator, for example the diameter of the piezoelectric element, or overlap the region of the piezoelectric element in the direction of vibration. In other words, a predominant longitudinal vibration preferably occurs when the diameter of the stepped end of the lambda/4 segment is smaller than 1.2 times the diameter of the remaining resonator, for example the diameter of the piezoelectric element. A predominant longitudinal vibration preferably occurs when a portion of the longitudinal vibration in the transmitted vibration of the lambda/4 segment is greater than 50 percent, in particular between 50 and 90 percent. Longitudinal vibrations can advantageously be implemented in very high frequencies and are particularly useful in applications in which fast response times are required, e.g., in sound waves or ultrasonic technologies. In contrast to flexural vibrations, longitudinal vibrations do not require bending of components, which leads to a lower mechanical stress and can prolong the service life of the components.

In a further preferred embodiment, at least one of the lambda/4 segments contains a stepped end larger in its dimension, wherein the stepped end functions as a combination of a flexural oscillator and a longitudinal oscillator. In other words, the diameter of the lambda/4 segment in this case is increased by 1.2 times to 1.4 times the diameter of the remaining resonator, for example the diameter of the piezoelectric element. In this respect, longitudinal and flexural vibrations occur simultaneously in non-negligible or comparable portions, so that the respective advantages of the two types of vibration can be obtained in combination.

In a further preferred embodiment, at least one of the lambda/4 segments contains a waist, which leads to a reduction of the resonance length of the resonator. A waist is, in particular, an at least partial reduction of the diameter of the at least one lambda/4 segment relative to the diameter of the remaining resonator, for example the diameter of the piezoelectric element. By means of the waist, a stiffness of the lambda/4 segment is reduced, whereby the vibration properties of the lambda/4 segment are changed. In order to maintain a constant (desired) resonance frequency, the length of the lambda/4 segment is shortened to such an extent that the change in the vibration behavior caused by the waist is canceled out by the reduction of the resonance length of the lambda/4 segment. Due to the reduction of the resonance length of the lambda/4 segment, the required installation space along the direction of vibration is advantageously reduced. A smaller structural size expands the application possibilities of the apparatus for generation and transmission of mechanical vibrations to media. The shape of the waist can preferably comprise any kind of taper, in particular round, in particular continuously round, stepped, and/or conical. A taper depth of the waist preferably comprises at least a reduction of the diameter by at least 10 percent, by at least 15 percent, by at least 20 percent, or by at least 25 percent of the diameter of the remaining resonator, for example the diameter of the piezoelectric element. The taper depth preferably corresponds to a maximum depth of the waist or an average depth of the waist along its extent. Preferably, a plurality of waists is provided.

In a further preferred embodiment, at least one of the substantially lambda/4 segments contains a waist, which leads to a change in the peak-to-peak amplitude and/or amplitude. The waist is, in particular, the waist described above. The introduced waist increases the amplitude of the lambda/4 segment, and the amplitude increased in this respect can be canceled out by an increase in the diameter of a stepped end of the lambda/4 segment (as already described above). By increasing the diameter, on the other hand, the resonance length of the lambda/4 segment can be (further) reduced in order to maintain a desired resonance frequency, whereby the required installation space along the direction of vibration is (still further) reduced.

In a further preferred embodiment, at least one of the lambda/4 segments contains a shaping at the active surface for optimizing the support surface in the case of non-planar media or container walls. Preferably, the shaping corresponds to the shape of the medium or the container wall and/or preferably the number of contact points is increased. For example, the number of contact points is increased by an indentation, recess, notch, or the like in an end face of the lambda/4 segment. For example, a prismatic, crescent, or semi-circular contour is provided for the transmission of mechanical vibrations to a cylindrical container. By increasing the contact points between the resonator and the shape of the medium or the container wall, the generated mechanical vibrations are transmitted more easily. A prismatic contour refers to the outer contour of a prism, i.e., the outline of the cross-section of a prism. A prism is a geometric body that has two parallel, equal-sized and identical surfaces (the bases) which are connected to each other by parallel side surfaces, for example a triangular, square, hexagonal, or another prism.

In a further preferred embodiment, it is provided that the lambda/4 segments consist of different metallic and/or ceramic materials. Ceramic materials are non-conductive and mostly chemically inert/resistant, for example to acids and/or oxidations, while metallic materials are favorable in production. Depending on the requirements, the lambda/4 segments can each consist of metallic or each of ceramic materials. Alternatively, at least one of the lambda/4 segments can consist of metallic material and another of the lambda/4 segments can consist of ceramic material.

Furthermore, the embodiments a) to m) mentioned in the following paragraphs are preferred, in particular also in any combination of two or more of these embodiments:

a) The resonant vibration is in the range of 15 kilohertz to 60 kilohertz, preferably 22 kHz to 30 kHz, e.g., 26 kHz.

b) The resonator is substantially cylindrical or cylinder-shaped.

c) The resonator is substantially rotationally symmetrical. The maximum diameter of the resonator is preferably between 1 millimeter and 500 millimeters, in particular between 5 millimeters and 150 millimeters, e.g., 40 mm.

d) The resonant vibration propagates longitudinally. The resonance frequency is determined via the length of the resonator.

e) The length of the resonator is one lambda/2 or a multiple of lambda/2, preferably one lambda/2.

f) The diameter of the substantially cylindrical resonator is ≤ one lambda/2.

g) The active surface is located on an end face of the substantially cylindrical resonator.

h) The maximum of the amplitudes along the planar active surface points of a resonator is between 0.1 and 300 micrometers, preferably between 1 and 30 micrometers, e.g., 8 micrometers.

i) The resonator consists of a metallic material. Alternatively, the resonator can consist of a non-metallic material.

j) The power transmitted from the resonator via the active surface to a medium by means of resonant mechanical vibrations is 1 watt to 2,000 watts, preferably 1 to 50 watts, e.g., 10 watts.

k) The resonator is mechanically connected to a further resonator.

In a further preferred embodiment, it is provided that the resonator is mechanically connected to a vibration exciter. In other words, a further lambda/2 resonance oscillator is provided, which is mechanically connected to the resonator. One of the two lambda/2 resonance oscillators comprises the piezoelectric element in order to excite both lambda/2 resonance oscillators to vibrate. The part of the surface of the resonator delimiting the resonator which is in contact with ambient air, coolant, or compressed gas, protective gas, or inert gas is not considered part of the active surface.

### Definitations and Terminology

Media (medium, media) are, for example, fluids, gases, liquids, melts, plasma, supercritical gases, liquid metals, dispersions, emulsions, cell suspensions, pastes, coatings, polymers, resins, and nanomaterials or mixtures of the aforementioned. Media can have different viscosities from 0 centipoise to 30,000,000,000 centipoise, preferably from 0.1 centipoise to 1,000,000 centipoise, e.g., 200 centipoise.

Resonator point is an element of the resonator. The resonator is the set of all resonator points.

Surface point (resonator surface point) is a point located on the surface of the resonator delimiting the resonator. The resonator surface is the set of all resonator surface points. The resonator surface can be from 0.01 square centimeters to 100,000 square centimeters, preferably from 10 square centimeters to 5,000 square centimeters, e.g., 1,000 square centimeters.

Active surface is the part of the surface of the resonator delimiting the resonator which is in contact with a medium, or a plurality of media, or with the wall of a container filled with a medium. The active surface can be from 0.01 square centimeters to 100 square centimeters, preferably from 0.1 square centimeters to 20 square centimeters, e.g., 1 square centimeter.

Active surface point is a point located on the part of the surface of the resonator delimiting the resonator which is in contact with a medium or with the wall of a container filled with a medium.

Active power is the power transmitted from the resonator via the active surface to a medium or a container filled with a medium by means of resonant mechanical vibrations. The active power can be over 1 watt, preferably 1 watt to 200 watts, e.g., 10 watts.

Vibrations are mechanical vibrations with an operating frequency of 0.1 kilohertz to 100 kilohertz, preferably 22 kilohertz to 30 kilohertz, e.g., 26 kilohertz. During the vibration, resonator points move regularly about a rest position.

Rest position (equilibrium position) is the position of all resonator points in the absence of vibrations.

Vibration displacement (displacement) indicates the instantaneous distance of a resonator point from its rest position. The vibration displacement for each surface point can be described by a combination of the displacement along the X, Y, and Z axes.

Amplitude is the amount of the largest possible distance of a resonator point from its rest position on the movement performed by this resonator point during the displacement.

Normal amplitude of a surface point is the amount of the largest possible distance of this surface point along the normal vector of this surface point on the movement performed by this surface point during the displacement.

Normal amplitude of an active surface point is the amount of the largest possible distance of this active surface point along the normal vector of this active surface point on the movement performed by this active surface point during the displacement.

A resonator can be any mechanical structure. A resonator can be, among other things, rod-, ring-, bell-, plate-, beam-, cuboid-, cylindrical-, spherical-, cube-, conical-, hollow cylinder-, polygon- or plate-shaped, rotationally symmetrical or non-rotationally symmetrical, preferably rod-, cylindrical- or beam-shaped and rotationally symmetrical, e.g., cylinder-shaped and rotationally symmetrical to the longitudinal axis of the cylinder shape. The material of a resonator can be any, preferably solid or liquid, e.g., solid. Materials for a solid resonator can be, for example, metals, non-metals, crystals, plant products, such as wood, ceramic, glass, polymers, or composite materials, preferably metals, e.g., titanium alloys. A resonator can consist of one part or of a plurality of connected sub-components, preferably of one or two parts, e.g., consist of one part.

### BRIEF DESCRIPTION OF THE DRAWINGS

The various embodiments of the invention mentioned in this application can be advantageously combined with each other, unless stated otherwise in individual cases.

FIG. 1 to FIG. 5 show embodiments which are explained on the basis of the associated drawings. They show:

FIG. 1 a schematic cross-sectional view of an apparatus with a resonator according to a first embodiment,

FIG. 2 a schematic cross-sectional view of an apparatus with a resonator according to a second embodiment,

FIG. 3 a schematic cross-sectional view of an apparatus with a resonator according to a third embodiment,

FIG. 4 a schematic cross-sectional view of an apparatus with a resonator according to a fourth embodiment, and

FIG. 5 a schematic cross-sectional view of an apparatus with a resonator according to a fifth embodiment.

### DETAILED DESCRIPTION

Detailed embodiments will now be described, which are illustrated by way of example in the accompanying drawings. The effects and features of these embodiments are described with reference to the accompanying drawings. In the drawings, like reference numerals denote like elements, and redundant descriptions are omitted. The present disclosure can be realized in various forms and is not to be understood as being limited only to the embodiments illustrated here. Rather, these embodiments are examples so that this disclosure is thorough and complete and fully conveys the aspects and features of the present disclosure to the person skilled in the art.

Methods, elements, and techniques that are not necessary for the person skilled in the art for a full understanding of the aspects and features of the present disclosure are therefore possibly not described. In the drawings, the relative sizes of elements, layers, and regions may be exaggerated for clarity.

As used herein, the term "and/or" includes all combinations of one or more of the listed elements. Furthermore, the use of "can" or "may" in the description of embodiments of the present disclosure refers to "one or more embodiments of the present disclosure." In the following description of embodiments, the terms in the singular can also include the plural, unless something else clearly emerges from the context.

Although the terms "first" and "second" are used for describing various elements, these elements should not be limited by these terms. These terms are only used to distinguish one element from another element. Thus, for example, a first element can be referred to as a second element, and likewise a second element can be referred to as a first element, without this deviating from the scope of the present disclosure. Expressions such as "at least one of," when preceded by a list of elements, modify the entire list and not just the individual elements of the list.

Terms such as "substantially," "approximately," and the like are used as terms of approximation and not as statements of degree and are intended to take into account the inherent deviations in measured or calculated values that are recognized by persons skilled in the art. If the term "substantially" is used in connection with a feature that can be expressed by a numerical value, the term "substantially" denotes a range of at least +/- 5 % of the value, which is centered on the value.

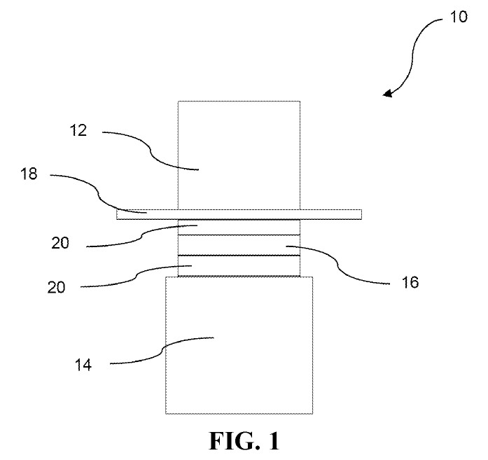

FIG. 1 shows a schematic cross-sectional view of an apparatus for generation and transmission of mechanical vibrations to media according to a first embodiment.

At least one resonator 10 consists of or comprises at least one lambda/2 resonance oscillator, which for each lambda/2 is assembled in a positive-fit and/or material-bonding and/or friction-locked manner from at least two substantially lambda/4 segments 12, 14, wherein the resonance length of the substantially lambda/4 segments 12, 14 is less than or equal to or greater than lambda/4, and their assembly results in a resonance length of at least one lambda/2. As shown in FIG. 1, the lambda/2 resonance oscillator is not only assembled from two substantially lambda/4 segments 12, 14, but further comprises a piezoelectric element 16 and at least one external body, such as a holding body 18 and/or one or at least two insulating disks 20. FIG. 1 shows an exemplary structure of the resonator. A first lambda/4 segment 12 is arranged at a holding body 18, which serves as a fastening structure for the resonator 10 at an external body. A structure of two insulating disks 20 with a piezoelectric element 16 arranged therebetween is arranged at the holding body 18. Then follows a second lambda/4 segment 14, which is arranged on the opposite side of the structure. In other words, the resonator 10 comprises the first and second lambda/4 segments 12, 14 at the respective opposite sides, and the at least one piezoelectric element 16 and at least one external body 18, 20 are arranged therebetween. In other words, the insulating disks 20 can also be omitted. Additionally, or alternatively, the holding body 18 can be omitted and at least one insulating disk 20 can be provided. The mentioned components of the resonator 10 are connected to one another in a positive-fit, material-bonding, and/or friction-locked manner.

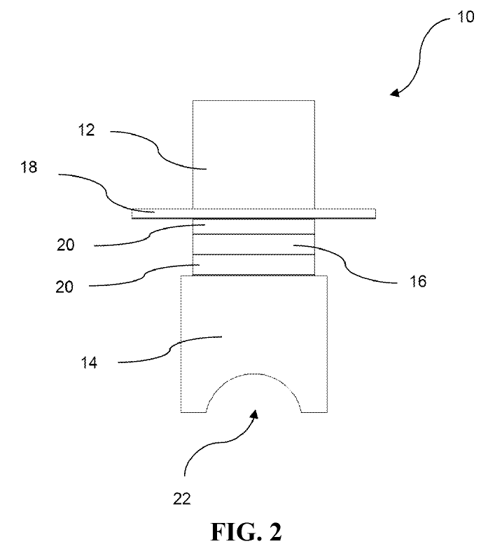

The lambda/4 segments 12, 14 are configured to have a resonance length less than or equal to lambda/4, wherein their assembly results in a resonance length of at least one lambda/2. The lambda/4 segments 12, 14 shown in FIG. 1 are preferably cylindrical bodies. The diameter of the lambda/4 segments 12, 14 is preferably equal to the diameter of the piezoelectric element 16, which is formed as a disk by way of example. What is meant is the (radial) diameter of the resonator 10 along the horizontal in FIG. 1. However, the diameter of at least one of the lambda/4 segments 12, 14 can differ from the diameter of the piezoelectric element 16. As shown in FIG. 1, the first lambda/4 segment 12 can preferably have the same diameter as the piezoelectric element 16, while the second lambda/4 segment 14 has a larger diameter. In this way, the vibration behavior of the respective lambda/4 segment 12, 14 can be changed or influenced and/or the design of the resonator can be adapted to a predetermined installation space. These advantages are explained in more detail by way of example on the basis of the embodiments illustrated in the following FIG. 2 to FIG. 5. In the following description, reference is made only to the respective differences. A repetitive description of features already described is omitted.

FIG. 2 shows a schematic cross-sectional view of an apparatus with a resonator 10 according to a second embodiment.

Compared to the embodiment illustrated in FIG. 1, the resonator 10 illustrated in FIG. 2 further comprises at least one indentation 22 in the end face of the second lambda/4 segment 14. The end face refers to an axial end of the resonator 10 (i.e., along the vertical in FIG. 2). The indentation 22 is formed as a semi-circle. A cylindrical container can be introduced into the indentation 22 in order to achieve as many contact points as possible between the second lambda/4 segment 14 and the container, whereby the vibration transmission to the container is improved. In this respect, for example, media located in the container can be excited by the mechanical vibration generated by the resonator 10. However, the present disclosure is not limited to an indentation 22 with a semi-circular shape. Rather, the shape of the indentation 22 can be adapted to any container surface or contour. By means of the indentation 22, the total length of the resonator 10 including the container along the axial direction can furthermore be shortened. Thus, the installation space required by the apparatus is reduced. Furthermore, the indentation 22 is not limited to the second lambda/4 segment 14. Instead of or in addition thereto, the first lambda/4 segment 12 can preferably comprise an indentation 22 as described herein.

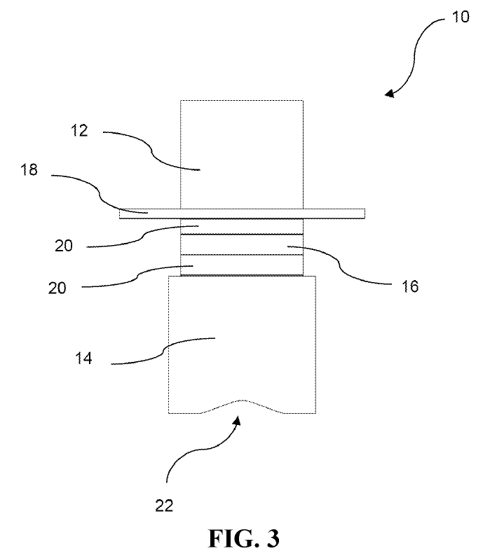

FIG. 3 shows a schematic cross-sectional view of an apparatus with a resonator 10 according to a third embodiment. Instead of a semi-circular indentation 22, an indentation 22 with a prismatic contour is provided here. Compared to a planar end face, the contact points of the second lambda/4 segment 14 can be increased relative to any non-planar contour of a container by means of the prismatic contour.

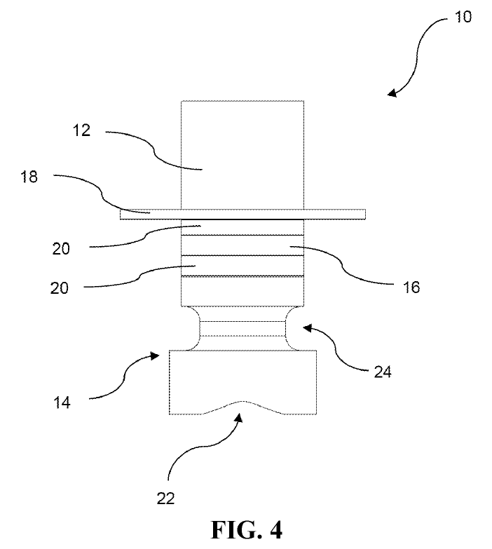

FIG. 4 shows a schematic cross-sectional view of an apparatus with a resonator 10 according to a fourth embodiment.

Compared to the embodiment shown in FIG. 3, the second lambda/4 segment 14 comprises a stepped end that is larger than the diameter of the piezoelectric element 16. In other words, the second lambda/4 segment 14 comprises a first section with a first diameter, which preferably corresponds to the diameter of the piezoelectric element 16, and a second section with a second diameter, which is larger than the first diameter. By means of the second section, the mass of the second lambda/4 segment 14 is increased. The influence of the mass increased in this respect on the vibration behavior of the second lambda/4 segment 14 can be compensated for, for example, by a reduction in the resonance length of the second lambda/4 segment 14 in order to maintain the resonance frequency. In other words, the total length of the resonator 10 along the axial direction (vertical in the image plane of FIG. 4) is reduced, whereby the resonator 10 can be designed more compactly and requires less installation space.

In addition, a waist 24 is preferably provided, which comprises a region with a reduction in the (radial) diameter of the second lambda/4 segment 14. The waist 24 is preferably arranged between the first section and the second section of the second lambda/4 segment 14. Because the waist 24 reduces the stiffness of the second lambda/4 segment 14 and in this respect changes the vibration behavior, the resonance length of the second lambda/4 segment 14 and thus the total length of the resonator 10 can be still further reduced while maintaining the same resonance frequency.

Although an indentation 22 with a prismatic contour is illustrated, it is understood that any contour of the indentation 22 can be used. Furthermore, it is understood that the embodiments shown with regard to the second lambda/4 segment 14 are analogously applicable additionally or alternatively to the first lambda/4 segment 12.

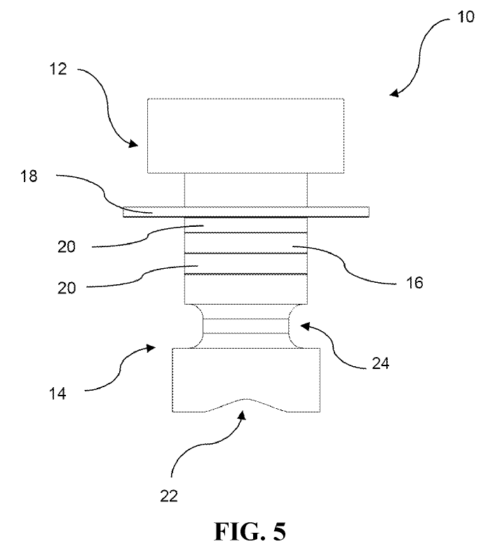

FIG. 5 shows a schematic cross-sectional view of an apparatus with a resonator 10 according to a fifth embodiment.

Compared to the embodiment shown in FIG. 4, the first lambda/4 segment 12 comprises a first section with a first diameter, which preferably corresponds to the diameter of the piezoelectric element 16, and a second section with a second diameter, which is larger than the first diameter. In this way, analogous to the additionally achieved mass described in FIG. 4, a shortening of the resonance length of the first lambda/4 segment 12 can be achieved. Preferably, the second diameter of the first lambda/4 segment 12 is larger than the second diameter of the second lambda/4 segment 14. In this way, respective different proportions of flexural vibration and longitudinal vibration in the generated mechanical vibrations can be achieved. For example, the first lambda/4 segment 12 vibrates in a combination of flexural and longitudinal vibration, while the second lambda/4 segment 14 is designed to vibrate predominantly as a longitudinal vibration.

At least one resonator 10 consists of or comprises at least one lambda/2 resonance oscillator, which for each lambda/2 is assembled in a positive-fit and/or material-bonding and/or friction-locked manner from two substantially lambda/4 segments 12, 14, at least one piezoelectric element 16 and other bodies 18, 20 or comprises these, wherein the resonance length of the substantially lambda/4 segments 12, 14 is less than or equal to lambda/4, and their assembly results in a resonance length of at least one lambda/2.

The substantially lambda/4 segments 12, 14 have at least one, any combination, or all of the following properties:

substantially lambda/4 segment 12, 14 with a stepped end that is larger in its dimension, which leads to a reduction in the resonance length of the resonator 10,

substantially lambda/4 segment 12, 14 with a stepped end that is larger in its dimension, wherein the stepped end functions as a flexural oscillator,

substantially lambda/4 segment 12, 14 with a stepped end that is larger in its dimension, wherein the stepped end functions as a longitudinal oscillator,

substantially lambda/4 segment 12, 14 with a stepped end that is larger in its dimension, wherein the stepped end functions as a combination of flexural oscillator and longitudinal oscillator,

substantially lambda/4 segment 12, 14 with a waist 24 for reducing the resonance length,

substantially lambda/4 segment 12, 14 with a waist 24 for changing the peak-to-peak amplitude / amplitude,

substantially lambda/4 segment 12, 14 with a shaping at the radiating surface (active surface) for optimizing the support surface in the case of non-planar media, wherein preferably the shaping corresponds to the shape of the medium or the number of contact points is increased, e.g., by a prismatic contour for transmission to a cylindrical medium and/or

the substantially lambda/4 segments 12, 14 consist of different materials.

### LIST OF REFERENCE NUMERALS

10 resonator

12 first substantially lambda/4 segment

14 second substantially lambda/4 segment

16 piezoelectric element

18 holding body

20 insulating disk

22 indentation

24 waist

1. An apparatus for generation and transmission of mechanical vibrations to media, comprising at least one resonator comprising at least one lambda/2 resonance oscillator, which for each lambda/2 is assembled from or comprises at least two substantially lambda/4 segments, at least one piezoelectric element, and at least one external body in a positive-fit and/or material-bonding and/or friction-locked manner, wherein a resonance length of the lambda/4 segments is less than or equal to lambda/4 and their assembly results in a resonance length of at least one lambda/2.

2. The apparatus according to claim 1, wherein at least one of the lambda/4 segments contains a stepped end larger in its dimension, which leads to a reduction of the resonance length of the resonator.

3. The apparatus according to claim 1, wherein at least one of the lambda/4 segments contains a stepped end larger in its dimension, wherein the stepped end functions predominantly as a flexural oscillator.

4. The apparatus according to claim 1, wherein at least one of the lambda/4 segments contains a stepped end larger in its dimension, wherein the stepped end functions predominantly as a longitudinal oscillator.

5. The apparatus according to claim 1, wherein at least one of the lambda/4 segments contains a stepped end larger in its dimension, wherein the stepped end functions as a combination of a flexural oscillator and a longitudinal oscillator.

6. The apparatus according to claim 1, wherein at least one of the lambda/4 segments contains a waist, which leads to a reduction of the resonance length of the resonator.

7. The apparatus according to claim 1, wherein at least one of the lambda/4 segments contains a waist, which leads to a change in peak-to-peak amplitude and/or amplitude.

8. The apparatus according to claim 1, wherein at least one of the lambda/4 segments contains a shaping at an active surface for optimization of a support surface in the case of non-planar media or container walls, wherein preferably the shaping corresponds to a shape of a medium or the container wall and/or wherein preferably a number of contact points is increased.

9. The apparatus according to claim 1, wherein the lambda/4 segments consist of various metallic and/or ceramic materials.

10. The apparatus according to claim 1, wherein the resonator is configured such that the resonant vibration is in a range from 15 kilohertz to 60 kilohertz.

11. The apparatus according to claim 1, wherein the resonator is substantially cylindrical.

12. The apparatus according to claim 1, wherein the resonator is substantially rotationally symmetrical.

13. The apparatus according to claim 1, wherein a maximum diameter of the resonator is between 5 millimeters and 150 millimeters.

14. The apparatus according to claim 1, wherein the resonator is configured such that the resonant vibration propagates longitudinally and its frequency is determined by the length of the resonator.

15. The apparatus according to claim 1, wherein the length of the resonator is lambda/2 or a multiple of lambda/2.

16. The apparatus according to claim 1, wherein the resonator consists of one part.

17. The apparatus according to claim 1, wherein the resonator consists of a metallic material.

18. The apparatus according to claim 1, wherein power transmitted from the resonator via the active surface to a medium by means of resonant mechanical vibrations is from 1 watt to 10,000 watts.

19. The apparatus according to claim 1, wherein the resonator is mechanically connected to a vibration exciter.

20. The apparatus according to claim 1, wherein the resonator is mechanically connected to at least one further resonator.
